(19) United States
(12) Patent Application Publication
(10) Pub. No.: US 2025/0355044 A1
(43) Pub. Date: Nov. 20, 2025

(54) ELECTRONIC DEVICE AND METHOD FOR RESTORING A STATE OF AN INTEGRATED CIRCUIT

(71) Applicant: Infineon Technologies AG, Neubiberg (DE)

(72) Inventors: Jürgen Alt, Holzkirchen (DE); Lukas Degle, Augsburg (DE)

(21) Appl. No.: 19/209,878

(22) Filed: May 16, 2025

(30) Foreign Application Priority Data
May 17, 2024 (DE) 10 2024 113 966.8

(51) Int. Cl. G01R 31/3185

(52) U.S. Cl. CPC G01R 31/318536

(57) ABSTRACT

In one example, an electronic device with an integrated circuit is provided. The integrated circuit includes a plurality of scan chains and a clock supply circuit for each group of one or more of the scan chains which have same length. The clock supply circuit is configured to supply a clock signal to the flip-flops of the group of scan chains. The clock supply circuit includes a detection circuit configured to detect, for at least one of the scan chains of the group, whether a bit sequence has been completely loaded into the scan chain. The clock supply circuit is configured to suppress the supply of the clock signal to the flip-flops of the group of scan chains in response to the detection circuit having detected that, for the at least one of the scan chains of the group, the bit sequence has been completely loaded into the scan chain.

### REFERENCE TO RELATED APPLICATION

This application claims priority to German Application number 10 2024 113 966.8, filed on May 17, 2024, the contents of which are hereby incorporated by reference in their entirety.

### BACKGROUND

Exemplary embodiments generally relate to electronic devices and methods for restoring a state of an integrated circuit.

Integrated circuits, e.g. microcontrollers (MCUs) as are used in vehicles must meet high quality standards. For this purpose, test circuits (in particular test control devices, such as an LBIST (Logic Built-In Self-Test) controller) are provided in devices which contain such circuits, which test circuits load test patterns into chains of scan flip-flops provided for that in the integrated circuit, have the contents of the scan flip-flops processed by the integrated circuit and evaluate the test result.

When the scan chains, i.e. the chains of scan flip-flops, are loaded with test patterns when testing is carried out during operation, data which should be available in the scan chains again after the testing in order to continue operation may be overwritten. Efficient approaches to addressing this issue are desirable, which should in particular be able to deal with the fact that the scan chains may have different lengths.

### SUMMARY

According to one embodiment, an electronic device with an integrated circuit is provided, wherein the integrated circuit has a plurality of scan chains which have different lengths at least to some extent, a clock signal source which is set up to provide a clock signal, and a clock supply circuit for each group of one or more of the scan chains which have same length, which clock supply circuit is set up to supply the clock signal to the flip-flops of the group of scan chains. The clock supply circuit has a detection circuit which is set up to detect, for at least one of the scan chains of the group, whether a bit sequence which should be loaded into the scan chain has been completely loaded into the scan chain and the clock supply circuit is set up to suppress the supply of the clock pulse to the flip-flops of the group of scan chains as a response to the detection circuit having detected that, for the at least one of the scan chains of the group, the bit sequence which should be loaded into the scan chain has been completely loaded into the scan chain.

### BRIEF DESCRIPTION OF THE DRAWINGS

The figures do not reproduce the actual size relationships, but rather are intended to serve to illustrate the principles of the various exemplary embodiments. Various exemplary embodiments are described below with reference to the following figures.

FIG. 1 shows an integrated circuit according to an embodiment, which is arranged in an electronic device.

FIG. 2 shows an electronic device with an integrated circuit.

FIG. 3 illustrates a storage process in four steps starting from an initial state for two scan chains.

FIG. 4 illustrates the loading of the scan chains of FIG. 3 in four steps starting from an “unloaded state”.

FIG. 5 shows an integrated circuit according to one embodiment.

FIG. 6 shows an electronic device with an integrated circuit according to one embodiment.

FIG. 7 shows a flowchart which illustrates a method for restoring a state of an integrated circuit according to one embodiment.

### DETAILED DESCRIPTION

The following detailed description refers to the accompanying figures, which show details and exemplary embodiments. These exemplary embodiments are described in such detail that a person skilled in the art can carry out the invention. Other embodiments are also possible and the exemplary embodiments can be changed in structural, logical and electrical terms without departing from the subject matter of the invention. The various exemplary embodiments are not necessarily mutually exclusive; rather, various embodiments can be combined with one another to produce new embodiments. In the context of this description, the terms “connected”, “attached” and “coupled” are used to describe both a direct and an indirect connection, a direct or indirect attachment and a direct or indirect coupling.

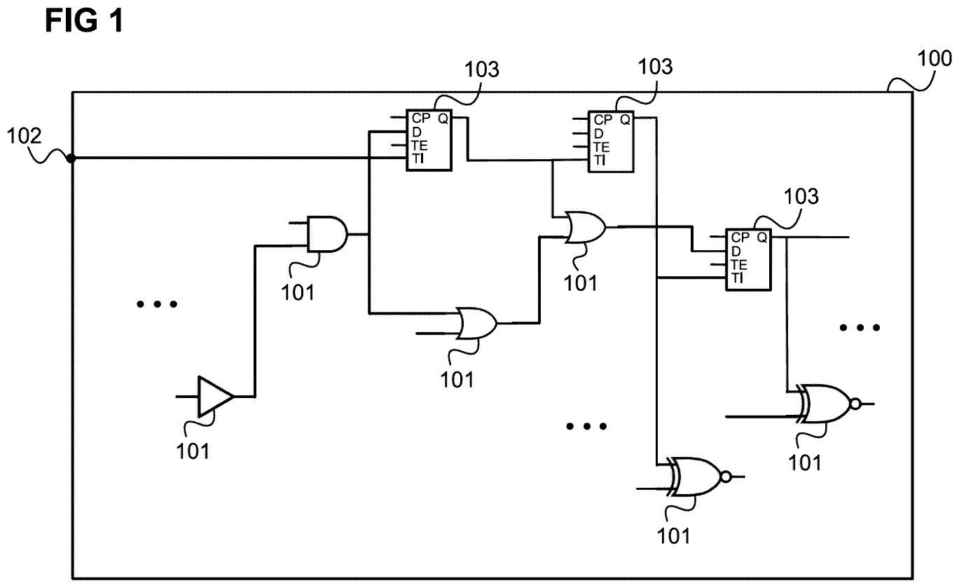

FIG. 1 shows an integrated circuit (or “chip”) 100 according to an embodiment, which is arranged in an electronic device.

The integrated circuit 100 is, for example, a microcontroller and arranged in an electronic device, for example in an ECU (electronic control unit) in a vehicle, or it is, for example, a chip card module for a chip card of arbitrary form factor.

The integrated circuit 100 has a multiplicity of logic gates 101 (AND gates, NON-OR gates, exclusive OR gates, inverters, and so on) that are connected to each other by connecting lines. The logic gates 101 are cells from a chip design library, and may also be more complex circuits (e.g., complex gates).

The integrated circuit 100 also has flip-flops, which are connected to the logic gates 101. At least some of the flip-flops are configured as scan flip-flops 103, so that test patterns for testing the integrated circuit 100 can be loaded into the scan flip-flops. A scan flip-flop is a D flip-flop with a multiplexer at the input, wherein an input of the multiplexer is used as data input D and the other input is used as test input (TI). The scan flip-flops 103 are connected to each other to form a chain by connecting the output of each scan flip-flop 103 (except the last of the chain) to the input of a subsequent scan flip-flop 103. The input of the first scan flip-flop 103 of the chain is connected to a test input pin 102 of the integrated circuit 100. CP refers to the clock input (for the sake of simplicity, connected to a clock signal line that is not illustrated). Via the test input pin 102, a test pattern is inserted by a test circuit into the chain of the scan flip-flops 103 (in each case via the test input). A test enable signal, which is supplied to a test enable input (TE), connection to the test enable signal line that is not illustrated for the sake of simplicity, switches the multiplexer of the scan flip-flop-from the data input (D) to the test input (TI) for testing.

According to various embodiments, the scan flip-flops 103 also each have a set input and/or a reset input, using which they can be set to 1 or 0 (not illustrated in FIG. 1).

When a test pattern has been loaded into the integrated circuit, it is processed by the integrated circuit, the results of processing are detected in the same or different flip-flops and read out from the integrated circuit for evaluation by the test circuit.

It should be noted that the integrated circuit 100 and the test circuit can also be part of the same chip. In the examples described here however, it is assumed that it is external to the integrated circuit, for example is is arranged on a printed circuit board together with the integrated circuit. In other words in these examples the integrated circuit 100 and the test circuit are part of the same electronic device.

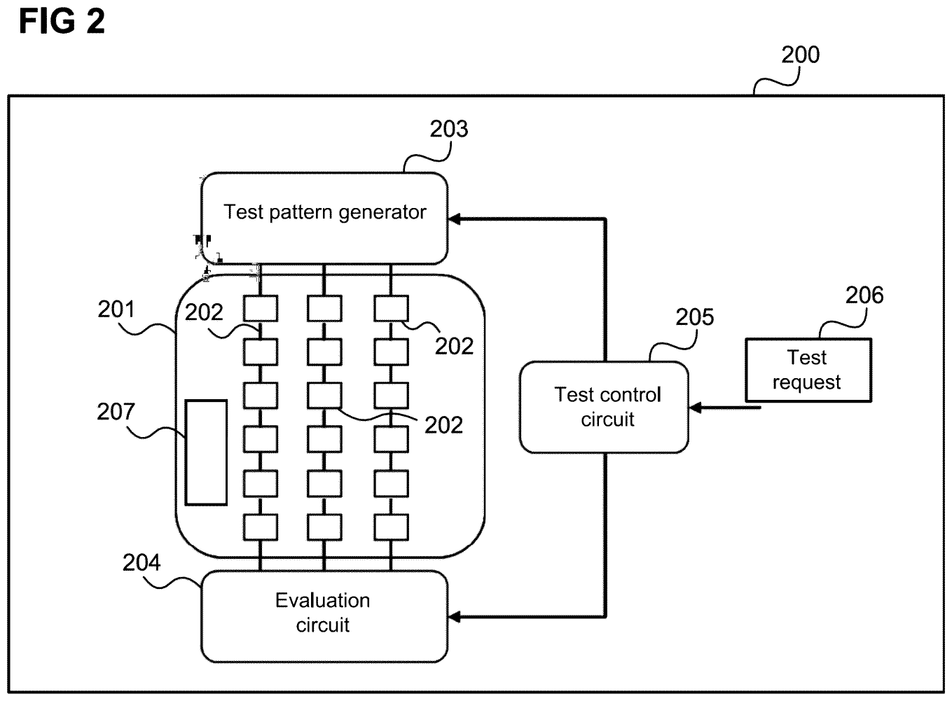

The test circuit typically contains a test control device (e.g. LBIST (Logic Built-In Self-Test) controller), a test pattern generator and an evaluation circuit. The test pattern that is shifted into the flip-flops 103 is generated by the test pattern generator. This is illustrated in FIG. 2.

FIG. 2 shows an electronic device 200 with an integrated circuit (chip) 201.

The chip 201 contains a multiplicity of scan flip-flop chains 202, as are explained with reference to FIG. 1.

A test pattern generator 203 generates test patterns sequentially and supplies them via test input pins to the scan flip-flop chains 202. A test pattern is for example understood to mean a pattern for a test iteration, which provides bit values for all of the scan flip-flops that are to be loaded in this test iteration. For example, a test pattern contains bits (test values) for all three scan flip-flop chains 202 in the example of FIG. 2.

In the example of FIG. 2, it is assumed that the results of processing the test patterns are detected by the scan (flip-flop) chains 202 themselves (and not by special monitoring flip-flops) via their D inputs and read out via test output pins by shifting them out of the chip 201 into an evaluation circuit 204 which determines whether the detected results correspond to the correct (reference) results.

A test control circuit 205 (also referred to as a test controller), in this case an LBIST (Logic Built-In Self-Test) controller, controls the test pattern generator 203 and the evaluation circuit 204. The LBIST controller 205 starts a test as a response to a test request message 206. The test request message 206 can for example be sent by a control unit (ECU) when a vehicle is started. In this case, it is normally acceptable that the contents of the scan chains 202 are simply reset (to a default value, e.g. to zero) after the testing, since normal operation can then be started easily. However, testing may also be necessary or desired during continuous operation. For example, in a vehicle, longer running times of devices may be desired or required, so that a test should be carried out during operation (i.e. operation is briefly paused and should then be continued seamlessly). In this case, resetting the scan chains 202 to a default value is not possible easily, because the values they had previously stored are required for the seamless continuation of operation.

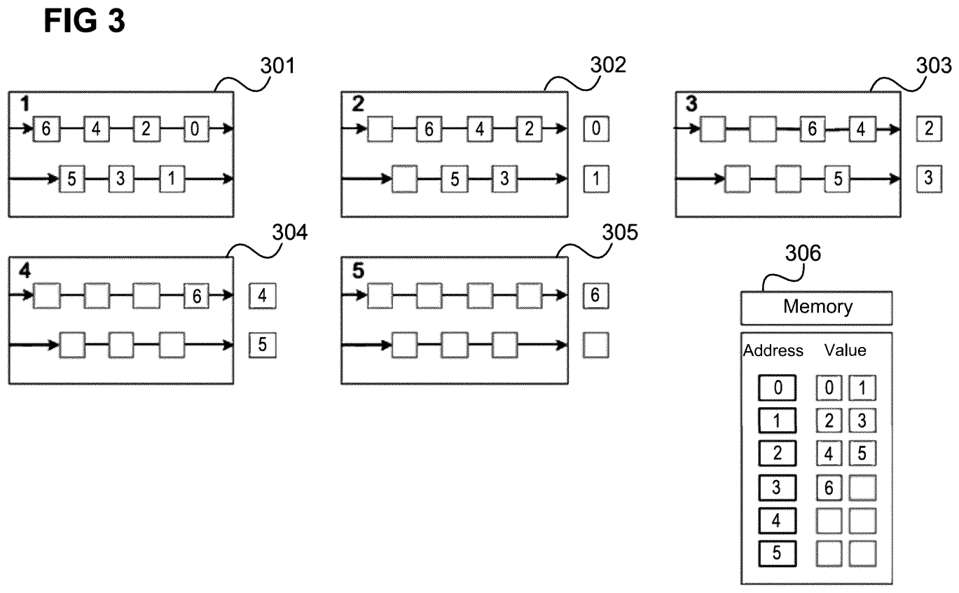

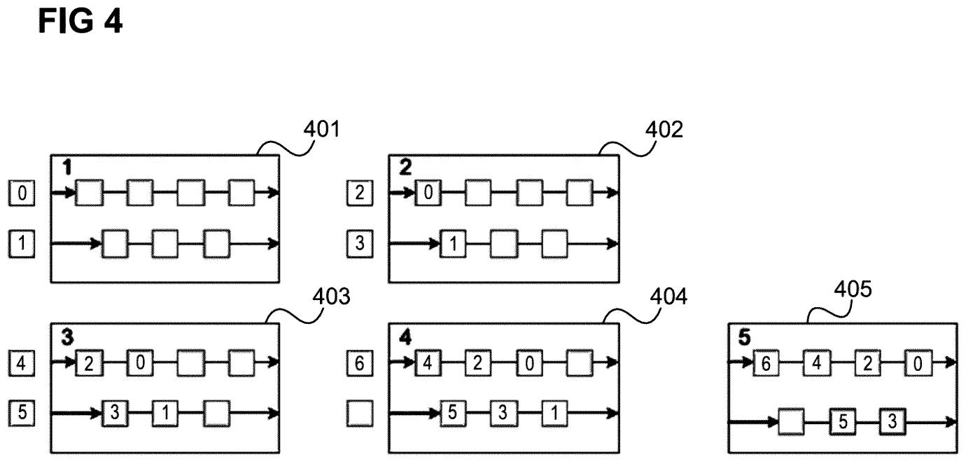

Depending on the use of the integrated circuit 201, it may therefore be necessary that the contents of the scan chains 202 after the test be equal to the contents of the scan chains before the test. For this purpose, before the test, that is to say before test patterns are written into the scan chains 202 (or while this is happening), the contents are stored (“Save”) in a memory 207 (e.g. on-chip, i.e. a memory of the integrated circuit, the connection of which to the scan chains 202 is not shown here for the sake of clarity) such as for example an SRAM (Static Random Access Memory) in order to be loaded back into the scan chains (“Load”) after the test. However, the difficulty arises here that the scan chains can have different lengths, as illustrated in FIG. 3 and FIG. 4 (using a simple example with very short scan chains).

FIG. 3 illustrates the storage process in four steps 302-305 starting from an initial state 301 for two scan chains.

For each step 301-305, the state of the first scan chain (shown at the top in each case) and the second scan chain (shown at the bottom in each case) is specified. The values of the scan chains are shifted out of the scan chains (to the right) for storage in a memory 306. The first scan chain starts with the values 6, 4, 2 and 0 and the second scan chain starts with the values 5, 3 and 1. Since in this example the values are not binary values (for better differentiation), each block of the scan chains (shown in FIG. 3 as a square in which the respective state is located) corresponds to a plurality of flip-flops (which store the respective state as a binary value). For example, each block corresponds to four flip-flops. Thus, the first scan chain is 16 flip-flops long and the second is 12 flip-flops long. Accordingly, each of the steps corresponds for example to four clock cycles (so that each bit is shifted one block further in each step). In each step, the one shifted out of the respective scan chain is stored in the memory 306.

After the third step 304, the contents of the second scan chain are completely stored in the memory 306. After the fourth step 305, the contents of the first scan chain are also completely stored in the memory. The values from the scan chains are stored here in the direction of ascending addresses.

FIG. 4 illustrates the loading of the scan chains of FIG. 3 in four steps 402-405 starting from an “unloaded state” (i.e. a state with “random” values resulting from the testing).

Loading functions in accordance with the storage by shifting (from the left) the values stored in the memory 406 into the scan chains.

After the third step 404, the second scan chain is completely loaded again. If the fifth step 405 is then executed, the first scan chain is completely loaded. However, since the second scan chain is shorter than the first scan chain, the first (i.e. rightmost) value of the second scan chain has been shifted out of the second scan chain again. Instead, an unknown value has been shifted from the left into the second scan chain. Therefore, the state of the second scan chain is not correct after the fifth step 405.

According to various embodiments, to avoid this problem, the clock pulse of a scan chain (or a plurality of scan chains) is stopped so that further loading is blocked after the correct number of clock cycles (i.e. bit-shift cycles), as corresponds to the length of the respective scan chain. This is made possible by a clock supply circuit that suppresses the clock supply to a respective scan chain when it has been completely loaded.

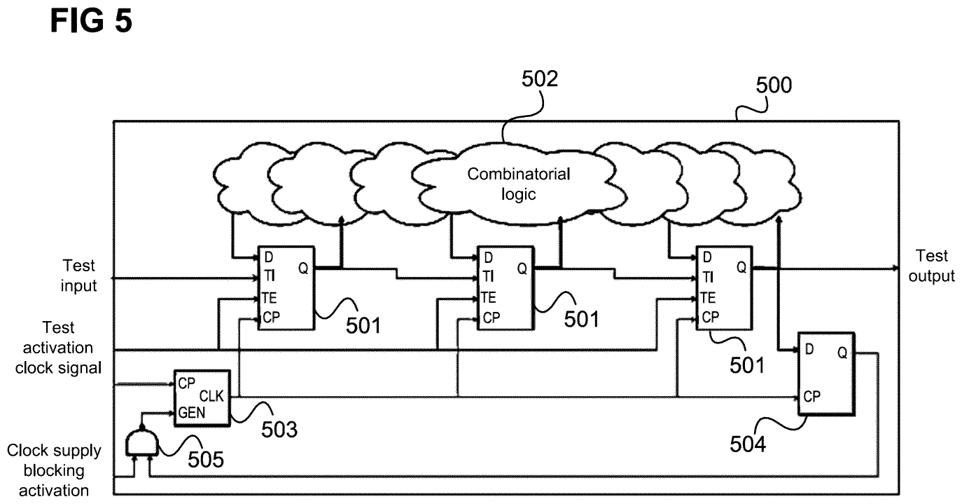

FIG. 5 shows an integrated circuit 500 according to one embodiment.

As described with reference to FIG. 1, the integrated circuit 500 contains a chain made of scan flip-flops 501 (i.e. a scan chain) which is connected by its data inputs (D) and by its outputs Q to a combinatorial logic 502 (as is formed in the example of FIG. 1 by the logic gates 101). In FIG. 5, the supply of the clock inputs CP is now also shown by means of a clock supply circuit: The clock supply circuit in this example consists of a clock supply circuit 503, a detection circuit 504 and an AND gate 505.

The clock supply circuit 503 receives a clock pulse from a clock signal source (e.g. a clock generation circuit, but can also be only one clock input which receives a clock pulse from a (chip-external) clock generation circuit of the respective electronic device) and forwards it to the clock inputs of the scan flip-flops 501 if a zero is applied at a clock blocking control input (GEN) of the clock supply circuit 503. Otherwise, it blocks the forwarding, i.e. the supply, of the clock pulse to the scan flip-flops 501. The detection circuit 504 is a D-flip-flop in this example, which is clocked to the clock pulse using the clock pulse that is possibly forwarded by the clock supply circuit 503 and is connected by its data input to the output of the last scan flip-flop of the chain. Its output is connected to an input of the AND gate 505. The other input of the AND gate 505 receives a signal which (if the value is 1) activates and (if the value is 0) deactivates clock suppression functionality. This signal can for example be supplied to the integrated circuit 500 via a corresponding control pin.

The mode of operation is now as follows:

Before loading a bit sequence (previously stored (in memory 207, 306, 406) prior to the testing) into the chain of scan flip-flops 501, all scan flip-flops 501 are set to zero (e.g. by means of their reset input).

The bit sequence is shifted from the left into the scan flip-flops 501, but they are provided with a leading one in the process, i.e., first a (binary) one is shifted into the scan flip-flops 501, which is followed by the bit sequence.

As soon as the leading one has been detected by the detection circuit 504 (i.e. has been stored, which is what happens when the leading one has been shifted out of the chain of scan flip-flops 501), the detection circuit outputs a one. This likewise sets the clock blocking control input to one (provided that clock suppression functionality is activated) and the clock supply circuit 503 blocks the supply of the clock signal to the chain of scan flip-flops 501. This means that no further bits are shifted into the chain of scan flip-flops 501 and the chain of scan flip-flops 501 stores the correct bit sequence, since only the leading one was shifted out.

In other words, the detection circuit 504 detects that a bit sequence has been completely loaded into a scan chain (that is to say determines this) if it receives (i.e., as a response to it receiving) a (binary) one.

The bit sequence which should be loaded into a scan chain can be supplied to the scan flip-flops via the test inputs or else via the data inputs, depending on where the memory is arranged (especially whether on-chip or off-chip).

It should be noted that scan chains which have the same length can be combined to form groups and can be provided with a common clock supply circuit (the detection circuit of which is connected only to the output of one of the scan chains).

It should further be noted that while in the example of FIG. 5, a “central” (i.e. a single) clock supply circuit 503 is provided for the entire chain of scan flip-flops 501, which suppresses (i.e., stops) the clock supply to all scan flip-flops 501 of the chain, a respective clock supply circuit 503 can also be provided at the clock input of each of the scan flip-flops 501 which receives the output of the AND gate 505 (or of the detection circuit 504 directly if the clock suppression functionality is always activated) and possibly interrupts the clock supply to the respective scan flip-flop 501.

In addition, it should be noted that the actual values (resetting to zero, providing the bit sequence to be stored with a leading one, activating the clock suppression functionality with one, suppressing clock supply with one at the clock blocking control input, etc.) are only one example and the relationships can also be reversed (e.g. resetting to one (e.g. by means of the set input of the scan flip-flops 501) and using a leading zero, etc.).

Resetting the flip-flops 501, controlling the charging and storage, and adding the leading one (generally “flag” or “flag bit”) take place for example by means of the test control circuit 205 (possibly in coordination with the test pattern generator 203). This can also activate the clock suppression functionality.

Bit sequences can be loaded into the scan flip-flops not only after testing, but also after other pauses of continuous operation, e.g. after an energy-saving state (i.e. operation in an energy-saving mode, e.g. standby mode).

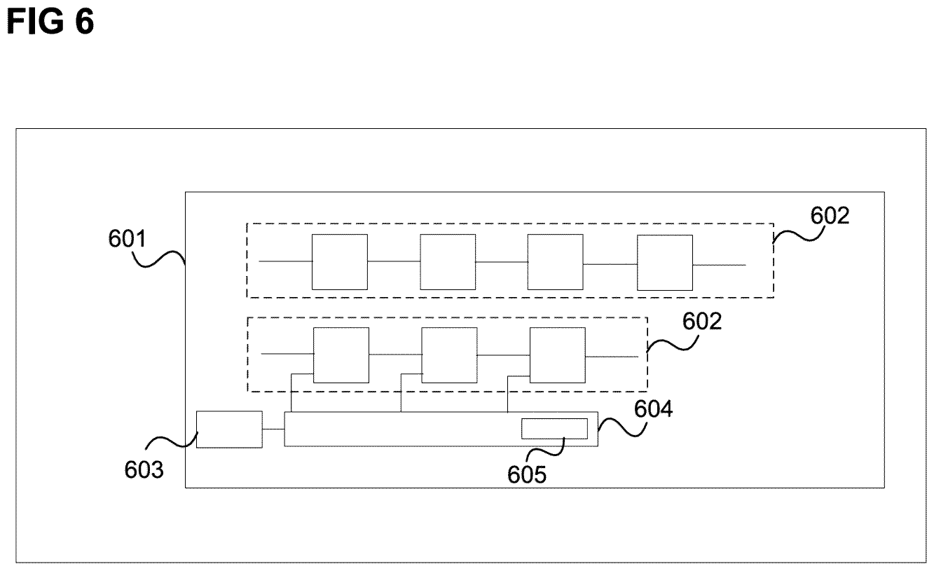

In summary, in accordance with various embodiments, provision is made of an electronic device as illustrated in FIG. 6.

FIG. 6 shows an electronic device 600 with an integrated circuit 601 according to one embodiment.

The integrated circuit 601 has a plurality of scan (flip-flop) chains 602 (i.e. chains made of a plurality of scan flip-flops in each case) which have different lengths at least to some extent (i.e. not all have the same number of flip-flops).

In addition, the integrated circuit 601 contains a clock signal source 603, which is set up to provide a clock signal (for the scan flip-flops) (this may be a clock generation circuit or even only one clock input which receives the clock signal from an external clock generation circuit (the electronic device 600)). The scan flip-flops forward values stored by them according to the clock signal supplied to them.

For each group of one or more of the (i.e. of the) scan chains 602 which have the same length (i.e. groups are formed from the scan chains 602, wherein the scan chains of a group have the same length), the integrated circuit 601 additionally contains a clock supply circuit 604 which is set up to supply the clock signal to the flip-flops of the group of scan chains (i.e. the scan flip-flops which belong to scan chains of the group) (i.e. supply them with the clock signal). The clock supply circuit 604 has a detection circuit 605 which is set up to detect, for at least one of the scan chains 602 of the group, whether a bit sequence which should be loaded into the scan chain 602 has been completely loaded into the scan chain and wherein the clock supply circuit is set up to suppress (i.e. to interrupt or to stop) the supply of the clock pulse to the flip-flops of the group of scan chains 602 as a response to the detection circuit having detected that, for the at least one of the scan chains 602 of the group, the bit sequence which should be loaded into the scan chain 602 has been completely loaded into the scan chain 602.

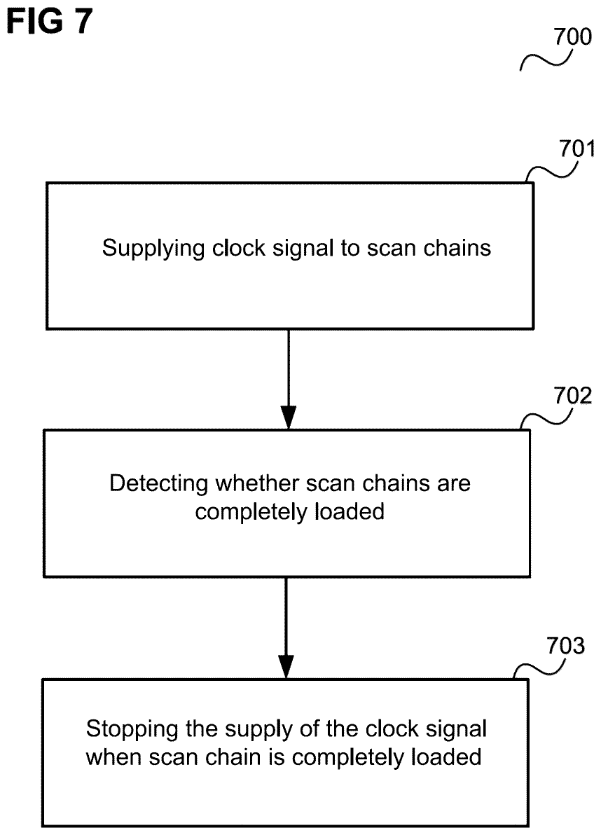

In accordance with various embodiments, a method as illustrated in FIG. 7 is provided.

FIG. 7 shows a flowchart 700 which illustrates a method for restoring a state of an integrated circuit (e.g. after a test or an energy-saving state of the integrated circuit) according to an embodiment.

In 701, a clock signal is supplied to the scan flip-flops of a plurality of scan chains, which have different lengths at least to some extent.

In 703, for each group of one or more of the scan chains which have the same length, a detection is made of whether, for at least one of the scan chains of the group, a bit sequence which should loaded into the scan chain has been completely loaded into the scan chain.

In 703, the supply of the clock pulse to the flip-flops of the group of scan chains is suppressed (i.e. stopped) as a response to it having been detected that, for at least one of the scan chains of the group, the bit sequence which should be loaded into the scan chain has been completely loaded into the scan chain.

Various exemplary embodiments are specified below.

Exemplary embodiment 1 is an electronic device as described with reference to FIG. 6.

Exemplary embodiment 2 is an electronic device according to exemplary embodiment 1, having a memory which is set up to store the bit sequence.

Exemplary embodiment 3 is an electronic device according to exemplary embodiment 1 or 2, wherein the detection circuit is connected to an output of the at least one of the scan chains of the group and is set up to detect that the bit sequence which should be loaded into the scan chain has been completely loaded into the scan chain as a response to it receiving a specified value from the output of the at least one scan chain.

Exemplary embodiment 4 is an electronic device according to exemplary embodiment 3, wherein the specified value is a binary one or a binary zero.

Exemplary embodiment 5 is an electronic device according to one of the exemplary embodiments 1 to 4, having a control circuit which is set up to set the scan flip-flops of the at least one scan chain to a specified binary value, to add the inverse binary value of the specified binary value to the bit sequence as the leading bit, and to load the expanded bit sequence into the scan chain by applying the expanded bit sequence to an input of the at least one scan chain.

Exemplary embodiment 6 is an electronic device according to exemplary embodiment 5, wherein the control circuit is set up to effect a pause in operation of the integrated circuit, wherein for each of the scan chains, it is set up to store the contents of the respective scan chain as a bit sequence before the pause in operation, which bit sequence should be stored in the respective scan chain after the pause in operation.

Exemplary embodiment 7 is an electronic device according to exemplary embodiment 5, wherein the control circuit is a test control circuit which is set up to perform a test of the integrated circuit, wherein for each of the scan chains, it is set up to store the contents of the respective scan chain as a bit sequence before the test, which bit sequence should be stored in the respective scan chain after the test.

Exemplary embodiment 8 is a method for restoring a state of an integrated circuit as described with reference to FIG. 7.

Although the invention has been shown and described primarily with reference to specific embodiments, it should be understood by those familiar with the technical field that numerous modifications can be made thereto with regard to configuration and details, without departing from the essence and scope of the invention as defined by the claims hereinafter. The scope of the invention is therefore determined by the appended claims, and the intention is for all modifications to be encompassed which come under the literal meaning or the scope of equivalence of the claims.

What is claimed is:

1. An electronic device with an integrated circuit, wherein the integrated circuit has:
a plurality of scan chains;
a clock signal source configured to provide a clock signal; and
a clock supply circuit for each group of one or more of the scan chains having a same length, wherein the clock supply circuit is configured to supply the clock signal to scan flip-flops of the group of scan chains;
wherein the clock supply circuit includes a detection circuit configured to detect, for at least one of the scan chains of the group, whether a bit sequence is completely loaded into the scan chain and wherein the clock supply circuit is configured to suppress the supply of clock pulse to the flip-flops of the group of scan chains in response to the detection circuit detecting that, for the at least one of the scan chains of the group, the bit sequence has been completely loaded into the scan chain.

2. The electronic device of claim 1, comprising a memory which is set up to store the bit sequence.

3. The electronic device of claim 1, wherein the detection circuit is connected to an output of the at least one of the scan chains of the group and is configured to detect that the bit sequence is completely loaded into the scan chain in response to the detection circuit receiving a specified value from the output of the at least one scan chain.

4. The electronic device of claim 3, wherein the specified value is a binary one or a binary zero.

5. The electronic device of claim 1, comprising a control circuit configured to set the scan flip-flops of at the least one scan chain to a specified binary value, to add an inverse binary value of the specified binary value to the bit sequence as a leading bit to generate an expanded bit sequence, and to load the expanded bit sequence into the scan chain by applying the expanded bit sequence to an input of the at least one scan chain.

6. The electronic device of claim 5, wherein the control circuit is configured to effect a pause in operation of the integrated circuit, wherein for each of the scan chains, the control circuit is set up to store contents of the respective scan chain as the bit sequence before the pause in operation.

7. The electronic device of claim 5, wherein the control circuit is a test control circuit configured to perform a test of the integrated circuit, wherein for each of the scan chains, the test control circuit is configured to store contents of the respective scan chain as the bit sequence before the test and store the bit sequence in the respective scan chain after the test.

8. A method for restoring a state of an integrated circuit, comprising:
supplying a clock signal to scan flip-flops of a plurality of scan chains; and
for each group of one or more of the scan chains which have the same length,
detecting whether, for at least one of the scan chains of the group, a bit sequence has been completely loaded into the scan chain; and
suppressing a supply of clock pulses to the flip-flops of the group of scan chains as a response to detecting that, for at least one of the scan chains of the group, the bit sequence has been completely loaded into the scan chain.

9. The method of claim 8, comprising detecting that the bit sequence has been completely loaded into the scan chain in response to detecting a specified value at an output of the scan chain.

10. The method of claim 9, comprising loading the scan flip-flops of the at least one of the scan chains with bit values having an inverse value with respect to the specified value;
appending a bit having the specified value to the bit sequence to generate an expanded bit sequence; and
shifting the expanded bit sequence through the scan flip-flops of the at least one scan chains until the bit having the specified value is detected at an output of the scan chain.

11. The method of claim 9, wherein the specified value is a binary one or zero.

12. The method of claim 8, further comprising, as part of a pause operation, storing contents of the scan flip-flops of the at least one scan chain as respective bit sequences.

13. A scan chain load control system, comprising:
a scan chain comprising a plurality of scan flip-flops;
a load detection flip-flop having an input coupled to an output of the scan chain;
and
clock supply circuit having a clock blocking control input that receives a clock suppression signal that depends on the output of the load detection flip-flop,
wherein the clock suppression signal has a value that causes the clock supply circuit to suppress clock pulses to the scan flip-flops when the output of the load detection flip-flop is a specified value.

14. The scan chain load control system of claim 13, wherein the specified value is a binary one or zero.

15. The scan chain load control system of claim 13, comprising:
a memory; and
a control circuit configured to
load the plurality of scan flip-flops with an inverse of the specified value;
append a bit having the specified value to a bit sequence stored in the memory to generate an expanded bit sequence; and
shift the expanded bit sequence into the scan chain to load the bit sequence into the scan chain.

16. The scan chain load control system of claim 15, comprising a control circuit configured to
determine to pause normal operation of the scan chain; and
store contents of the scan flip-flops in the memory.

17. The scan chain load control system of claim 13, comprising a plurality of scan chains receiving clocks signals from the clock supply circuit, wherein for each group of scan chains having a same number of scan flip-flops, the output of one scan chain is coupled to the load detection flip-flop.

18. The scan chain load control system of claim 13, comprising combinatorial logic having an input coupled to an output of the load detection flip-flop, the combinatorial logic configured to output the clock suppression signal in response to the output of the load detection flip-flop having the specified value.

19. The scan chain load control system of claim 18, wherein the combinatorial logic comprises an AND gate.

20. The scan chain load control system of claim 18, wherein the load detection flip-flop comprises a D flip-flop having a Delay input coupled to the output of the scan chain, a clock input coupled to an output of the clock supply circuit, and an output coupled to the input of the combinatorial logic.
